(19) United States
(12) Patent Application Publication
(10) Pub. No.: US 2024/0348332 A1
(43) Pub. Date: Oct. 17, 2024

(54) LASER TRANSMITTER CHARACTERIZATION FOR ACCURATE LASER AGING

(71) Applicant: Calix, Inc., San Jose, CA (US)

(72) Inventors: Harold Roberts, San Jose, CA (US); Marta Seda, San Jose, CA (US); Pete Lee, San Jose, CA (US)

(21) Appl. No.: 18/301,416

(22) Filed: Apr. 17, 2023

(51) Int. Cl. H04B 10/079; H04B 10/50

(52) U.S. Cl. CPC H04B 10/0795; H04B 10/503

(57) ABSTRACT

Systems and techniques for laser transmitter characterization for accurate laser aging are described herein. A set of bias current-temperature pairs is collected for a laser diode. A bias current-temperature curve is calculated for the laser diode using the set of bias current-temperature pairs. A timestamp is assigned to the bias current-temperature curve. The bias current-temperature curve and the timestamp are stored in a non-volatile memory device communicatively coupled to a laser device that includes the laser diode. The bias current-temperature curve and the timestamp are transmitted to a cloud-based storage facility.

### TECHNICAL FIELD

Embodiments described herein generally relate to laser aging and, in some embodiments, more specifically to characterization of laser transmitters for accurate laser aging prediction.

### BACKGROUND

Lasers such as those used in optical networking have a finite lifespan. As a laser ages, the diode can utilize more electrical current to produce the desired light output. The laser can also function erratically or fail to operate when the diode reaches end-of-life. An aging laser diode can lead to increased error rates and inconsistent signal transmission. The user of a laser diode may wish to predict an accurate aging curve for a laser to predict a remaining lifespan of the laser diode.

### BRIEF DESCRIPTION OF THE DRAWINGS

In the drawings, which are not necessarily drawn to scale, like numerals can describe similar components in different views. Like numerals having different letter suffixes can represent different instances of similar components. The drawings illustrate generally, by way of example, but not by way of limitation, various embodiments discussed in the present document.

FIG. 1 is an example graph that illustrates laser light-current-voltage characteristics.

FIG. 2 is an example graph that illustrates laser lifetime variation with temperature.

FIG. 3 is an example graph that illustrates temperature dependence of light versus current.

FIG. 4 is an example graph that illustrates a hazard rate characteristic curve for unscreened laser diodes.

FIG. 5 is a block diagram illustrating an example of an environment and a system for bias current-temperature collection for Laser Transmitter Characterization for Accurate Laser Aging, according to various embodiments.

FIG. 6 is a block diagram illustrating an example of an environment and a system for characteristic-based laser aging for Laser Transmitter Characterization for Accurate Laser Aging, according to various embodiments.

FIG. 7 is a flow diagram illustrating an example of a method for bias current-temperature collection for Laser Transmitter Characterization for Accurate Laser Aging, according to various embodiments.

FIG. 8 is a flow diagram illustrating an example of a method for characteristic-based laser aging for Laser Transmitter Characterization for Accurate Laser Aging, according to various embodiments.

FIG. 9 is a block diagram illustrating an example of a machine upon which one or more embodiments can be implemented.

### DETAILED DESCRIPTION

Laser bias current monitoring has been used as a conventional indicator of laser aging. A maximum bias current threshold can be set and used to initiate notifications for proactive servicing of a laser. Setting a fixed threshold to notify users is problematic because laser bias current varies by laser lots, by individual devices, and by temperature. Picking a bias current threshold for notifications is therefore prone to false positives or negatives. The systems and techniques discussed herein allow customized laser characterization to set accurate and meaningful thresholds for prediction of laser degradation or failure.

In an example, a temperature dependent bias current curve can be characterized for each laser during manufacturing and testing. The temperature dependent bias current curve can be stored in nonvolatile memory of the laser device hardware that can be referenced while the laser is in service to monitor laser aging via calculation of a bias current increase that is normalized for temperature.

In an example, a temperature dependent bias current curve can be calculated and characterized for each laser device during run-time (e.g., during operation in the field) using environmentally caused laser temperature variation and bias current monitoring. The temperature dependent bias current curve can be stored in nonvolatile memory of the laser device hardware that can be referenced while the laser is in service to monitor laser aging via calculation of a bias current increase that is normalized for temperature.

Laser diodes are a fundamental component for optical fiber communication and also one of the components most prone to failure. A laser diode emits coherent light when the laser drive current crosses a ‘threshold current’ whereby the device changes from operating as a light emitting diode (LED) transmitting incoherent light to lasing with coherent light above the threshold current.

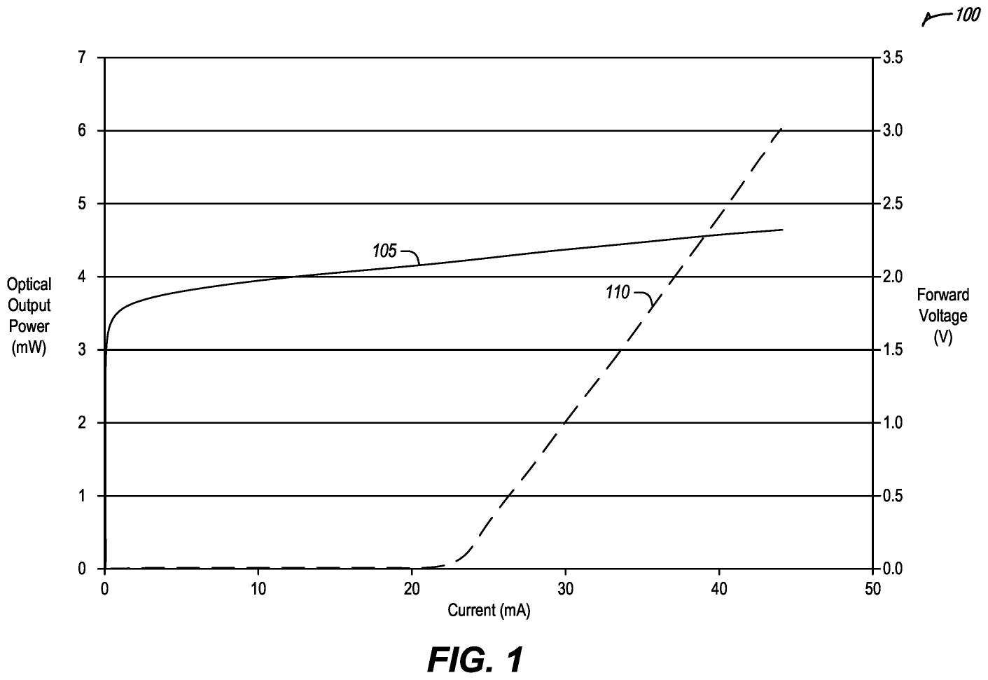

FIG. 1 an example graph 100 that illustrates laser light-current-voltage characteristics. A laser is generally operated above the threshold current at a bias current 110 for normal operation which produces the desired optical power 105. The reason current is used rather than voltage is that the laser has a well-defined mostly linear light output with current (past the threshold current) as shown in the graph 100 and the diode maintains a diode characteristic with respect to voltage.

The bias current is generally controlled by a feedback circuit whereby a “back facet” photodiode monitor detects the optical power level and a bias current circuit adjusts the laser drive current to maintain a constant optical power output level over the life of the laser. A laser has two facets that emit light. The front facet emits the majority of optical power for use in communications by coupling the power into an optical fiber. The laser is designed to emit minimal light from the back facet, however the ratio of optical power of the front facet divided by the back facet power is constant. The constant ratio between the front facet and the back facet makes it possible to use the back facet power as a proxy or reference for the front facet power coupled to the optical fiber. Other facets of the laser diode emit no light.

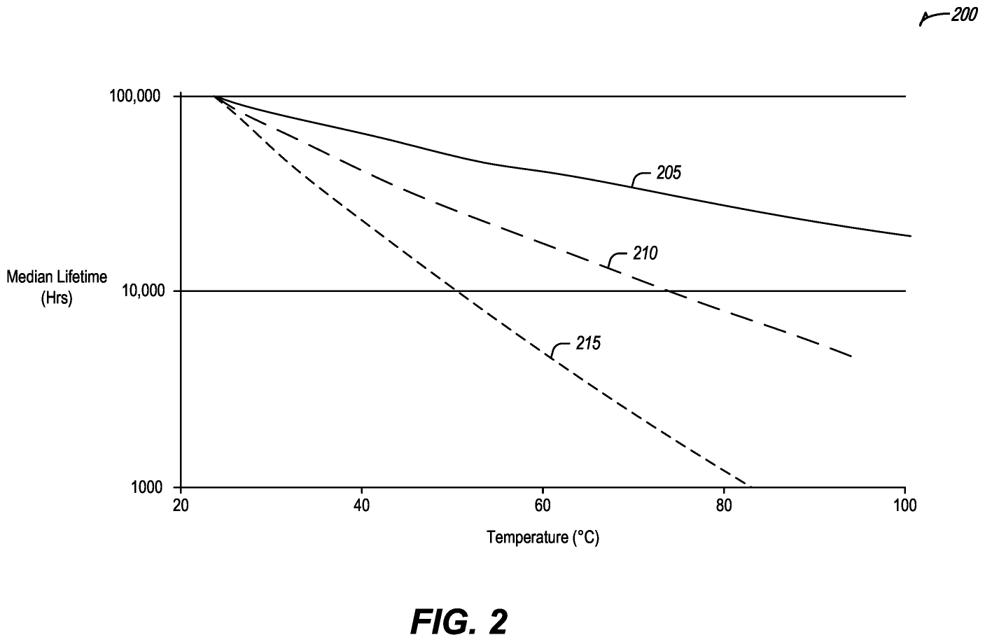

FIG. 2 is an example graph 200 that illustrates laser lifetime variation with temperature. Lasers become less efficient at higher temperatures. Thus, lasers at higher temperatures require higher bias current to maintain the same output power. This higher temperature also generally accelerates the aging of the laser as shown in the graph 200 illustrating median lifetime of a first laser with an activation energy of 0.2 electron volts (eV) 205, a second laser with and activation energy of 0.4 eV, and a third laser with an activation energy of 0.7 eV.

The back facet monitor feedback control circuit effectively maintains a constant power because photodiode responsivity is generally insensitive to temperature and can accurately measure power output over wide environmental conditions. Using the back facet monitor measurements the laser current drive circuit will fluctuate over temperature and over the life of the laser due to aging, all to maintain constant output optical power.

Laser transmitters are often equipped with sensors and in the case of International Telecommunications Union (ITU) Passive Optical Network (PON) specifications, such as Gigabit-capable PON (GPON), 10 gigabit-capable symmetrical PON (XGS-PON) and other ITU and Institute of Electrical and Electronics Engineers (IEEE) PONs, laser transmitters (and receivers) are expected to comply with certain requirements called Optical Line Supervision (OLS) specifications. Included in the OLS specifications are Temperature and Bias Current data elements that are collected by the optical line terminal/optical network unit (OLT/ONU) and are made available to a management system. The accuracy of these measurements is +/−3° Celsius (C) for temperature and +/−10% for bias current but the repeatability is tighter at +/−1°° C. and +/−5% respectively. The systems and techniques discussed herein increase the repeatability of temperature and bias current calculation based on predicted laser aging.

It is possible to set a generic threshold for bias current for a given laser type to trigger a notification that the laser is entering a phase of end-of-life so that the laser might be replaced before service failure occurs due to the bias current being unable to maintain the specified optical power or the current being high enough to cause thermal damage. However, a generic threshold cannot be accurate enough to avoid false positive or false negative notifications because the bias current change due to temperature is not accounted for in the generic threshold. A generic threshold also fails to capture bias current variability between different lasers and the accuracy of the current and temperature measuring circuits. To create a notification for impending laser failure, output fluctuations that are not indicative of laser aging or failure raise the threshold to notify at a higher level than needed to prevent false alerts and thereby make the aging warning/alarm non-functional because the laser can fail prior to reaching the elevated bias current threshold or a false alarm may be generated prior to significant laser aging.

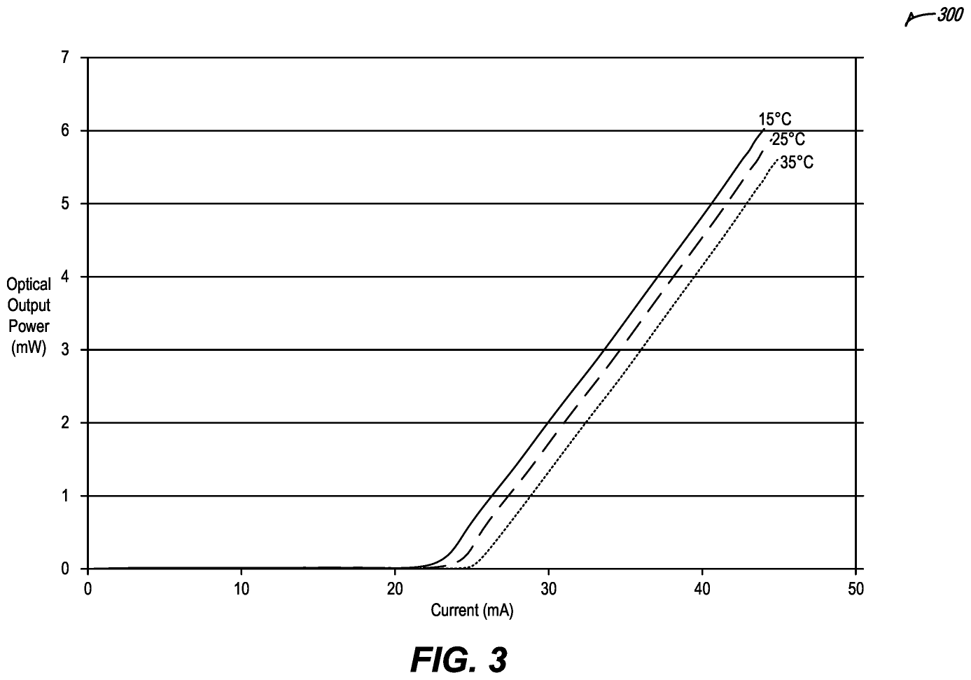

FIG. 3 is an example graph 300 that illustrates temperature dependence of light versus current. A reference model of the thermal behavior of the laser diode can reduce error related to bias current change with temperature. This is illustrated in the graph 300 for lasers operating at 15° C., 25° C., and 23° C. This approach has been outlined in patent U.S. Pat. No. US2019/0089110 A1, titled “Laser failure early warning indicator.”

The systems and techniques discussed herein simultaneously solve problems caused by bias current threshold errors due to (1) bias current changes with temperature for the individual laser being monitored (e.g., variances in individual laser bias current vs temperature curves for individual lasers), (2) nominal bias current variances for individual lasers at standard temperature, and (3) temperature probe errors due to: a) probe not placed directly at the laser cavity, b) thermal resistance between laser cavity and the temperature probe, and c) other errors of the temperature probe.

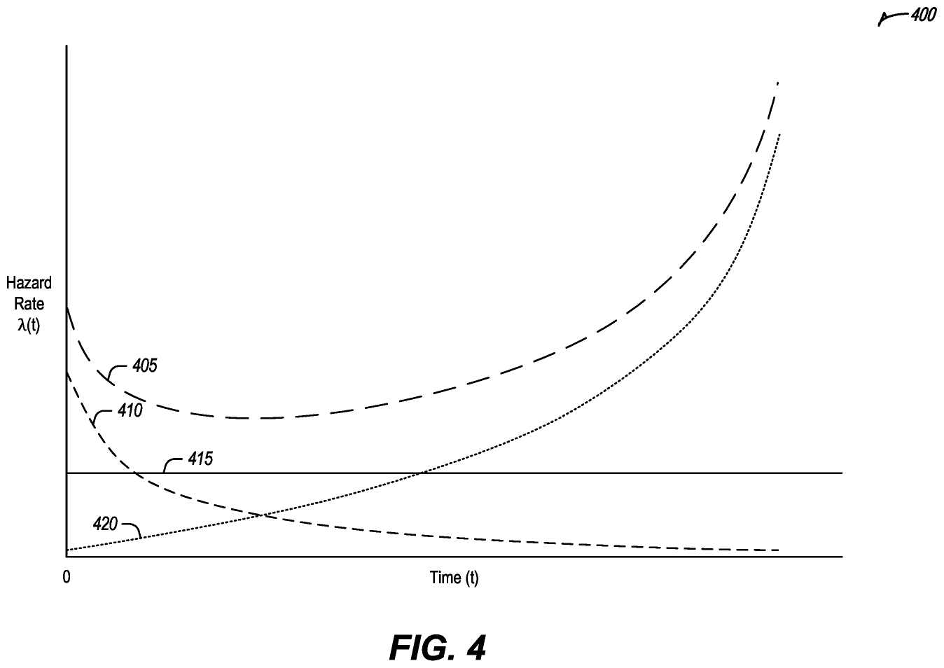

FIG. 4 is an example graph 400 that illustrates a hazard rate characteristic curve for unscreened laser diodes. Multiple curves can be stored over time as a laser goes through its useful life. For example, a laser can have significant but normal changes to the bias current/temperature curve in infancy (e.g., as shown by an infant mortality curve 410) then operates in a quasi-stable adolescent or adult stage (e.g., as indicated by the relatively stable portion of the composite aging curve 405) and finally the bias current/temperature curve can change significantly in a mature or old-age stage of life (e.g., as shown by a wear out curve 420). The rate of change of the bias current/temperature curve can be more indicative of failure than the absolute change.

The laser includes the laser diode, associated drive circuitry, and other associated electronics. The laser comprises local non-volatile memory sufficient to store multiple individualized models of the bias current measurements over temperature with sufficient resolution and range to meet the accuracy needs for the laser end of life warning. Each measurement is time stamped according to when the measurement was made. In an example, the data can be stored in a cloud-based storage system communicatively coupled to the laser. In an example, the individualized models over time are uploaded to a centralized data cloud for analysis. Typical curves the cloud can analyze could look like those in the graph 400 if the bias current is normalized for temperature. For example, a composite bathtub curve 405, an infant mortality 410, an external hazards value 415, and a wear out curve 420 can be analyzed to predict aging for a laser. Additionally or alternatively, the bias current/temperature curves over time could be made into a three dimensional surface. In an example, the cloud can be able to download individualized algorithms for threshold criteria for each laser to be stored locally.

A locally stored model can be created using a variety of techniques. In an example, during a manufacturing test phase, the laser environmental temperature is purposely varied from the lowest to highest operating temperature for calibration purposes and bias current/temperature pairs are noted and stored into the local non-volatile memory of the laser. The data pairs are used for comparison purposes to future data pairs captured during field operation of the laser. The creation of the manufacturing test phase curve covers a specified range of laser operational temperature. By definition, the reference curve reflects the laser characteristics prior to aging (e.g., as a data element of a laser birth certificate, etc.).

In an example, during field operation, the laser naturally experiences environmental temperature variation. The bias current/temperature curves are stored during run time for comparison to future bias current/temperature pairs during normal laser field operation. Runtime curve calculation does not incur the time or cost of the manufacturing test phase temperature calibration and can be applied to lasers which were not programmed with their own “birth certificate,” including lasers already operating in the field or being placed into field operation from inventory. In an example, calibration current-temperature pairs and runtime current-temperature curves are stored for comparison to future current-temperature pairs.

While the temperature measurement sensor and the bias current sensor can have systemic error (e.g., as shown by an external hazard line 415), the errors are controlled because pairs of bias current and temperature measurements are stored as doublets and changes to outputted bias current at a given outputted temperature are evaluated as an indicator of aging. The repeatability of the measurements allows for accurate aging prediction given that any systemic error will be small over a small current range. If the repeatability error is zero, the change in systemic error remains constant as current changes.

In an example with maximum error using a birth certificate doublet, an error of 3 degrees in temperature means that a laser temperature of 50° C. is actually outputted as 53° C. The three degree error is the same over the entire temperature range, within the repeatability error of 1° C. The temperature is associated with a specific outputted birth bias current (e.g., 1.1 amp (A)) but the actual current is really 1.0 A (e.g., the reading is 10% high). The increase in bias current for a 1 degree temperature increase is 1%. This results in a birth certificate doublet of 53° C., 1.1A.

In an example with maximum repeatability error using an old age doublet at some years of operation later, another measurement is obtained at what the sensor measures as 53° C. again. Repeatability is measured at +/−1° C., so the error can only be +/−1° C. indicating a true temperature of 52° C. or 54° C., otherwise the absolute error of +/−3° C. would be violated. A current output of 1.4A is read so the new doublet is 53° C., 1.4A. Without any repeatability error for the current measurement, the same systematic error is read as 10% high with the actual current being 1.272 A. But this reading is at an actual temperature of 49° C., so the current reading is 1% higher if measured at the original temperature of 50° C. It is determined what percent the current has increased at a given temperature to determine whether it has crossed a threshold level to notify of an aging event. The readings of 1.4A/1.1A=27% current increase. The actual increase is 1.272A/1.0A=27% current increase. But if the temperature had really been 50° C. as indicated in the birth certificate doublet, the current would be 1% higher=28% current increase. In an example with some current error could lead to a worst case current error of +/−5% or 10% total.

In an example that averages repeatability errors, repeatability errors can be mitigated by taking numerous measurements at one time and averaging the measurements. The averaging reduces the errors to bring the 10% error from bias current repeatability down to low single digit percentages. Conversely, a conventional reference model approach suffers from the systematic errors which are larger and impossible to average out.

An Arrhenius equation can be used to set notification thresholds. Depending on cloud analysis engine output, different methods of threshold setting could be used. For example, tabulating an age of the laser depending on operating minutes and temperature of operation (e.g., assigning an acceleration factor for laser minutes of operation at higher temperatures). In an example, an individualized laser bias current increase threshold can be calculated from when the laser was first installed in the field to current operating characteristics. For example, a warning can be set at 20% current increase at 50° C. compared to a curve captured in manufacturing test at 50° C. or bias current at 50° C. captured within X hours of initial operation. Similarly a notification could be set at 30% current increase under the conditions described above. In an example, a threshold of change of current over time at any given temperature can be set and an inflection point can be identified to trigger a notification. For example, a current increase of 10% occurred during the past week of operation whereas in the previous year of operation the current increase was only 5%.

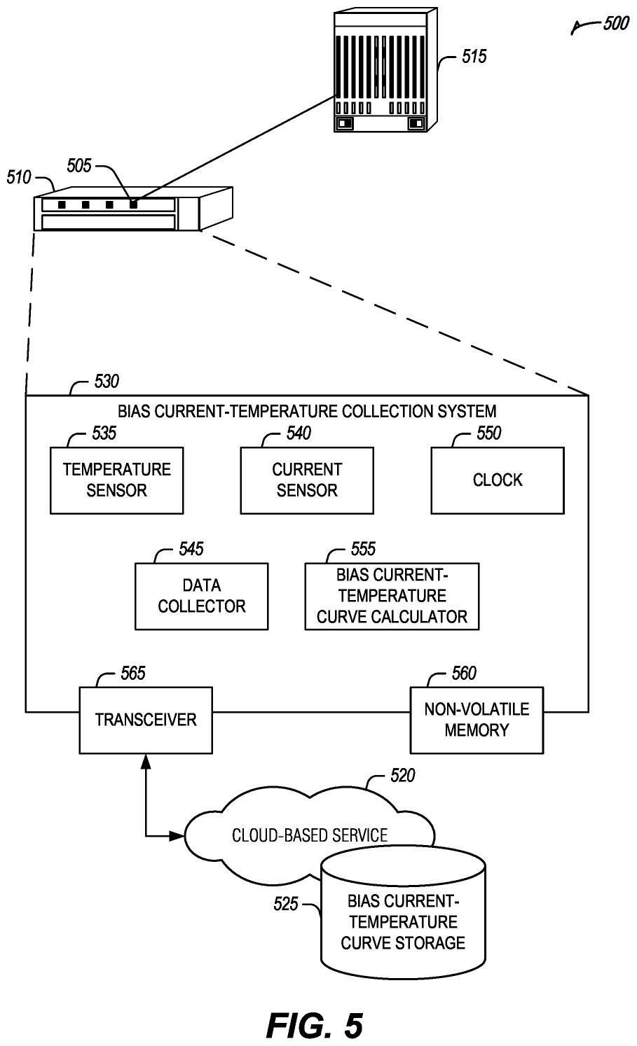

FIG. 5 is a block diagram illustrating an example of an environment and 500 a system 530 for bias current-temperature collection for Laser Transmitter Characterization for Accurate Laser Aging, according to various embodiments. The environment 500 can include a laser diode 505 included in an optical network unit (ONU) 510. The laser diode 505 can transmit and receive optical data signals to and from an optical line terminal 515. The environment 500 can include a cloud-based service 520 that includes a storage facility 525 that includes bias current-temperature curve data. While the examples provided herein discuss a laser diode of an ONU, it should be understood that the laser diode 505 can be included in a variety of laser devices (e.g., an optical line terminal (OLT), the ONU 510, other laser equipped devices, etc.).

The system 530 can be communicatively connected to the ONU 510. In an example, the system 530 can be a bias current-temperature collection system. The system 530 can provide features as discussed in FIGS. 1 to 4. The system 530 can include a variety of components including a temperature sensor 535, a current sensor 540, a data collector 545, a clock 550, a bias current-temperature curve calculator 555, non-volatile memory 560, and a transceiver 565. The components of the system 530 can be implemented as hardware devices (e.g., dedicated physical components, field programable gate arrays, application specific integrated circuits, etc.) or can be implemented in software (e.g., as computer instructions stored on computer-readable media and executed by at least one hardware processor, etc.) of the ONU 510.

The temperature sensor 535 and the current sensor 540 can be coupled to a back facet of the laser diode 505. In an example, the laser diode can transmit and receive optical data signals in a passive optical network (PON). The back facet can experience temperature and current values that can be used to calculate temperature and current data for a front facet responsible for optical transmissions.

The data collector 545 collects a set of bias current-temperature pairs for the laser diode 505. For example, the data collector 545 can collect current and temperature pairs from the temperature sensor 535 and the current sensor 540. In an example, the current-temperature pair provides a current value (e.g., in milliamps (mA), etc.) and a temperature (e.g., in degrees Celsius (C), etc.) for the laser diode 505 at a point in time. In an example, a ratio can be applied to light measurements taken at the back facet to approximate light values present at the front facet.

In an example, an environmental temperature of the laser diode 505 can be adjusted from a lowest operating temperature to a highest operating temperature (e.g., of a designated design operating temperature range, etc.) during manufacturing testing of the laser diode 505. The set of bias current-temperature pairs can comprise bias current-temperature pairs collected at a variety of temperatures from the lowest operating temperature to the highest operating temperature. For example, the laser diode 505 can have a designated operating temperature range of 0 degrees C. to 75 degrees C. and bias current-temperature pairs can be collected at five degree increments as the environmental temperature of the laser diode 505 is increased from 0 degrees C. to 75 degrees C. It will be understood that a variety of static and/or random intervals can be used to collect bias current-temperature pairs.

In an example, the set of bias current-temperature pairs are collected at a variety of environmental temperatures experienced by the laser diode 505 during operation. In an example, the laser diode 505 can be in operation and a variety of bias current-temperature pairs can be collected as the laser diode 505 operates at various temperatures. For example, a schedule of operating temperatures can be used to trigger collection of bias current-temperature pairs for the laser diode 505 as the operating temperature of the laser diode 505 reaches temperatures specified in the schedule of operating temperatures. Thus allows collection of bias current-temperature pairs to establish a bias current-temperature curve for a laser diode 505 already in operation.

The bias current-temperature curve calculator 555 calculates a bias current-temperature curve for the laser diode 505 using the set of bias current-temperature pairs. For example, the set of bias current-temperature pairs can be plotted as a graph or other representation to establish a baseline operation of the laser diode 505 at various temperatures. For example, at 35 degrees C. the laser diode 505 could have a current of 45 mA. In an example, a temperature error rate can be calculated for the temperature sensor 535 at the laser diode 505 and the bias current-temperature curve can be adjusted using the temperature error rate. For example, if the temperature sensor 535 consistently measures the temperature at three degrees higher than the actual temperature, the temperature value in the bias current-temperature pair can be decreased by three degrees. In an example, a current error rate can be calculated for the current sensor 540 at the laser diode 505 and the bias current-temperature curve can be adjusted using the current error rate. For example, if the current sensor 540 consistently measures the current at 0.2 mA lower than the actual current, the current value in the bias current-temperature pair can be increased by 0.2 mA.

The clock 550 assigns a timestamp to the bias current-temperature curve to provide a historical record of bias current-temperature curve generation to allow for comparisons between current bias current-temperature pairs and a curve generated from pairs collected during manufacture testing or during initial curve generation for in-service laser diodes. The bias current-temperature curve is stored in the non-volatile memory 560 of a laser device (e.g., the ONU 510, etc.). For example, the curve can be stored in flash memory of the laser device (e.g., the ONU 510, etc.).

The a transceiver 565 transmits the bias current-temperature curve to the cloud-based service 520 for storage in the cloud-based storage facility 525. In an example, the bias current-temperature curve can be transmitted during a management communication of the PON. In an example, the bias current-temperature curve can be transmitted to the cloud-based storage facility 525 at set or random intervals (e.g., every 30 minutes, 30 days, when network utilization is low, etc.). In an example, a current bias current-temperature pair can be collected for the laser diode 505. The current bias current-temperature pair can be transmitted to the cloud-based storage facility 525. An age value can be received for the laser diode 505 based on the current bias current-temperature pair and the age value can be stored in the non-volatile memory 560 communicatively coupled to the laser device 510.

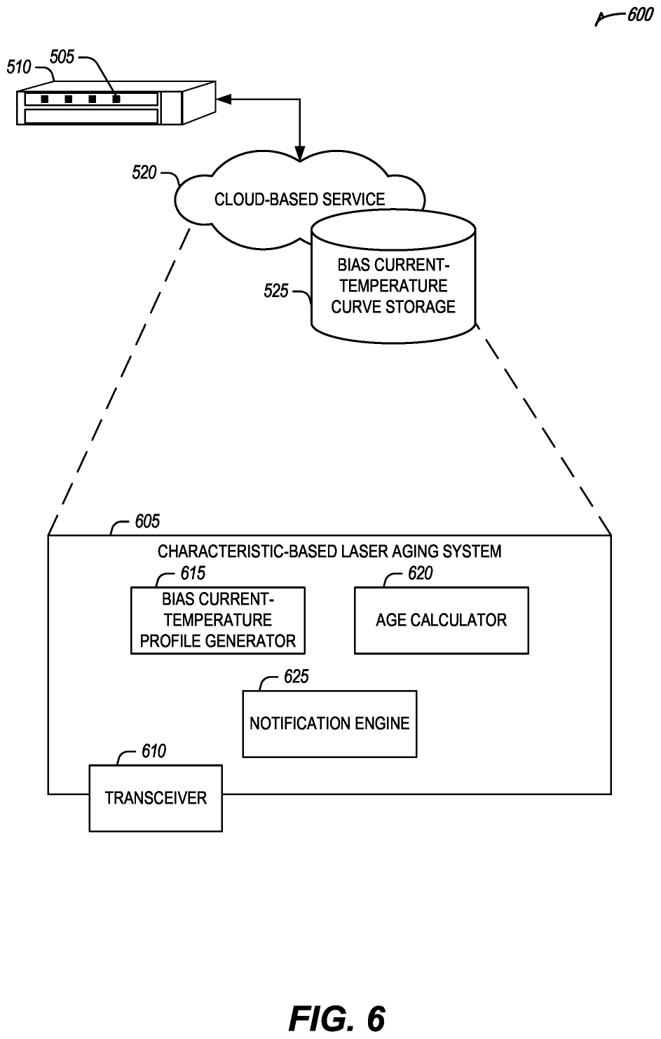

FIG. 6 is a block diagram illustrating an example of an environment 600 and a system 605 for characteristic-based laser aging for Laser Transmitter Characterization for Accurate Laser Aging, according to various embodiments. The environment 600 can include a laser diode 505 included in an optical network unit (ONU) 510. The laser diode 505 can transmit and receive optical data signals to and from an optical line terminal 515. The environment 600 can include a cloud-based service 520 that includes a storage facility 525 that includes bias current-temperature curve data.

The system 605 can be communicatively connected to the ONU 510. In an example, the system 605 can be a characteristic-based laser aging system. The system 605 can provide features as discussed in FIGS. 1 to 5. The system 605 can include a variety of components including a transceiver 610, a bias current-temperature profile generator 615, an age calculator 620, and a notification engine 625. The components of the system 605 can be implemented as hardware devices (e.g., dedicated physical components, field programable gate arrays, application specific integrated circuits, etc.) or can be implemented in software (e.g., as computer instructions stored on computer-readable media and executed by at least one hardware processor, etc.) of the ONU 510.

The transceiver 610 receives a set of bias current-temperature curves for the laser diode 505. The set of bias current-temperature curves have timestamps between a first time and a subsequent second time. For example, the set of bias current temperature curves can be collected from time periods during manufacture testing of the laser diode 505 and/or during a time period of initial baseline creation for a device already placed in service. The bias current-temperature profile generator 615 evaluates the set of bias current-temperature curves to calculate a bias current-temperature profile for the laser diode 505. In an example, the laser diode 505 transmits and receives optical data signals in a passive optical network (PON). In an example, the laser diode 505 is included in the ONU 510.

The transceiver 610 receives a current bias current-temperature pair for the laser diode 505. The age calculator 620 calculates an age of the laser diode 505 by evaluating the current bias current-temperature pair with the bias current-temperature profile of the laser diode. The age of the laser diode 505 indicates an operational life stage of the laser diode 505. In an example, a number of operating minutes of the laser diode 505 can be calculated at a temperature of the current bias current-temperature pair. An acceleration factor can be determined for the temperature using the bias current-temperature profile and the age of the laser diode 505 can be calculated by applying the acceleration factor to an aging algorithm and processing the number of operating minutes using the aging algorithm. In an example, an individualized laser bias current increase threshold can be calculated by comparing the bias current-temperature profile of the laser diode 505 to a current bias current-temperature curve. The bias current-temperature profile of the laser diode 505 can be established at initial installation of the laser diode and the age of the laser diode 505 can be determined by comparing the current bias current-temperature pair to the individualized laser bias current increase threshold. In an example, a threshold of change of current over time can be set for a range of temperatures using the bias current-temperature profile. It can be identified that the current bias current-temperature pair is an inflection point based on a comparison of the current bias current-temperature pair to the threshold of change of current over time. The age of the laser diode 505 can be determined based on the inflection point.

The notification engine 625 can determine that the age of the laser diode 505 is outside a laser diode age threshold. A laser aging notification can be generated for the laser diode 505 and the laser aging notification can be transmitted to a user computing device.

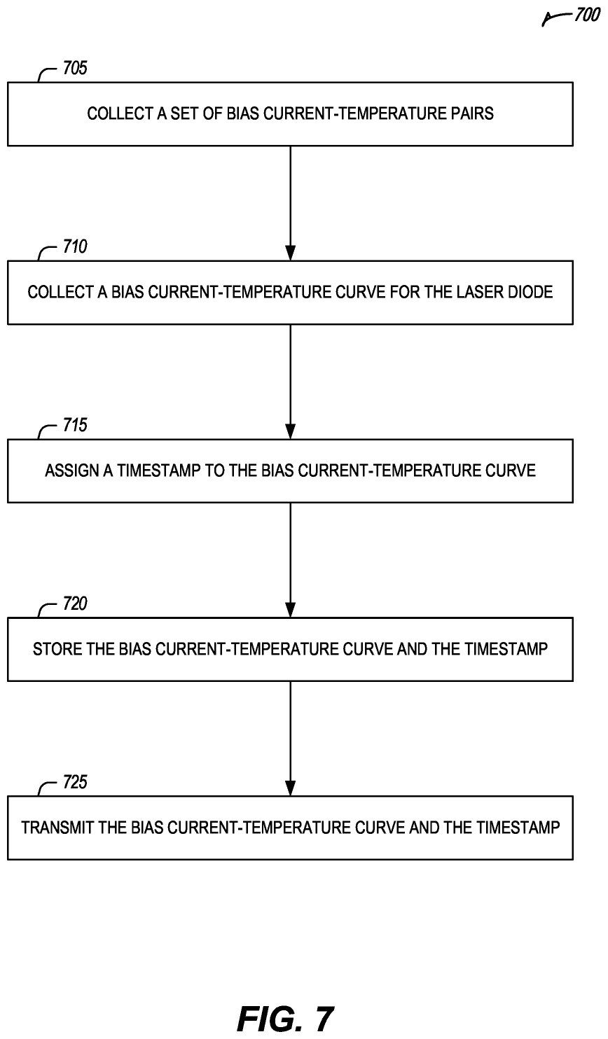

FIG. 7 is a flow diagram illustrating an example of a method 700 for bias current-temperature collection for Laser Transmitter Characterization for Accurate Laser Aging, according to various embodiments. The method 700 can provide features as described in FIGS. 1 to 6.

A set of bias current-temperature pairs is collected (e.g., by the data collector 545 as described in FIG. 5, etc.) for a laser diode (e.g., at operation 705). In an example, the laser diode can transmit and receive optical data signals in a passive optical network (PON). In an example, an environmental temperature of the laser diode can be adjusted from a lowest operating temperature to a highest operating temperature during manufacturing testing of the laser diode. The set of bias current-temperature pairs can comprise bias current-temperature pairs collected at a variety of temperatures from the lowest operating temperature to the highest operating temperature. In an example, the set of bias current-temperature pairs can be collected at a variety of environmental temperatures experienced by the laser diode during operation.

A bias current-temperature curve is calculated (e.g., by the bias current-temperature curve calculator 555 as described in FIG. 5, etc.) for the laser diode using the set of bias current-temperature pairs (e.g., at operation 710). In an example, a temperature error rate can be calculated for a temperature sensor at the laser diode and the bias current-temperature curve can be adjusted using the temperature error rate. In an example, a current error rate can be calculated for a current sensor at the laser diode and the bias current-temperature curve can be adjusted using the current error rate.

A timestamp is assigned (e.g., by the clock 550 as described in FIG. 5, etc.) to the bias current-temperature curve (e.g., at operation 715). The bias current-temperature curve and the timestamp is stored in a non-volatile memory device (e.g., the non-volatile memory 560 as described in FIG. 5, etc.) communicatively coupled to a laser device that includes the laser diode (e.g., at operation 720).

The bias current-temperature curve and the timestamp are transmitted (e.g., by the transceiver 565 as described in FIG. 5, etc.) to a cloud-based storage facility (e.g., at operation 725). In an example, a current bias current-temperature pair can be collected for the laser diode. The current bias current-temperature pair can be transmitted to the cloud-based storage facility. An age value can be received for the laser diode based on the current bias current-temperature pair and the age value can be stored in the non-volatile memory device communicatively coupled to a laser device.

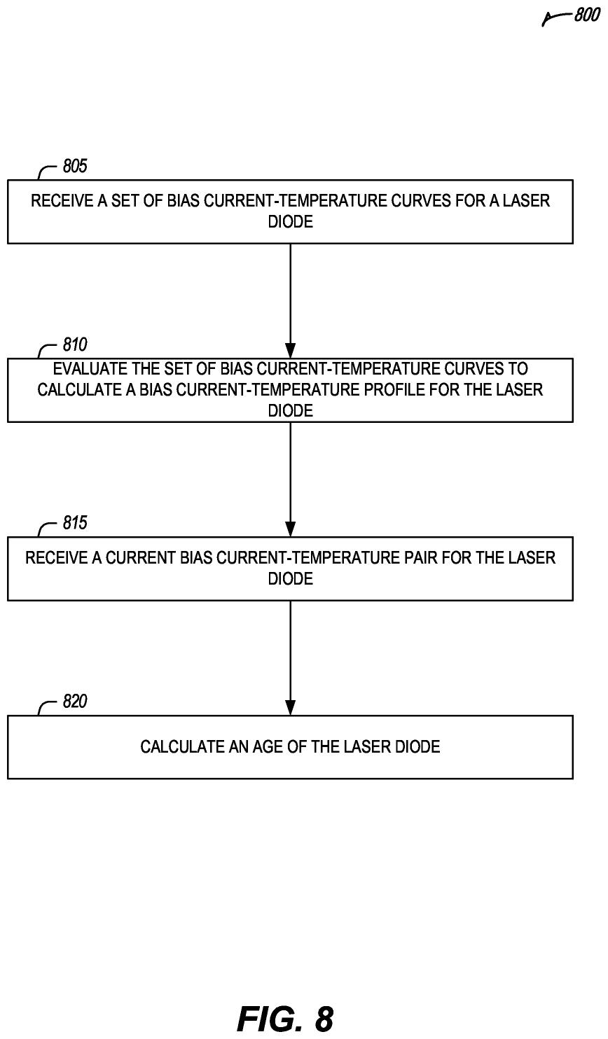

FIG. 8 is a flow diagram illustrating an example of a method 800 for characteristic-based laser aging for Laser Transmitter Characterization for Accurate Laser Aging, according to various embodiments. The method 800 can provide features as described in FIGS. 1 to 7.

A set of bias current-temperature curves is received (e.g., by the transceiver 605 as described in FIG. 6, etc.) for a laser diode (e.g., at operation 805). In an example, the set of bias current-temperature curves have timestamps between a first time and a subsequent second time. In an example, the laser diode can transmit and receive optical data signals in a passive optical network (PON). In an example, the laser diode can be included in an optical networking unit (ONU).

The set of bias current-temperature curves is evaluated (e.g., by the bias current-temperature profile generator 615 as described in FIG. 6, etc.) to calculate a bias current-temperature profile for the laser diode (e.g., at operation 810).

A current bias current-temperature pair is received (e.g., by the transceiver 605 as described in FIG. 6, etc.) for the laser diode (e.g., at operation 815). An age of the laser diode is calculated (e.g., by the age calculator 620 as described in FIG. 6, etc.) by evaluating the current bias current-temperature pair with the bias current-temperature profile of the laser diode (e.g., at operation 820). In an example, the age of the laser diode indicates an operational life stage of the laser diode. In an example, a number of operating minutes of the laser diode can be calculated at a temperature of the current bias current-temperature pair. An acceleration factor can be determined for the temperature using the bias current-temperature profile and the age of the laser diode can be calculated by applying the acceleration factor to an aging algorithm and processing the number of operating minutes using the aging algorithm.

In an example, an individualized laser bias current increase threshold can be calculated by comparing the bias current-temperature profile of the laser diode to a current bias current-temperature curve. In an example, the bias current-temperature profile of the laser diode can be established at initial installation of the laser diode. The age of the laser diode can be determined by comparing the current bias current-temperature pair to the individualized laser bias current increase threshold.

In an example, a threshold of change of current over time can be set for a range of temperatures using the bias current-temperature profile. It can be identified that the current bias current-temperature pair is an inflection point based on a comparison of the current bias current-temperature pair to the threshold of change of current over time and the age of the laser diode can be determined based on the inflection point.

In an example, it can be determined that the age of the laser diode is outside a laser diode age threshold. A laser aging notification can be generated for the laser diode and the laser aging notification can be transmitted to a user computing device.

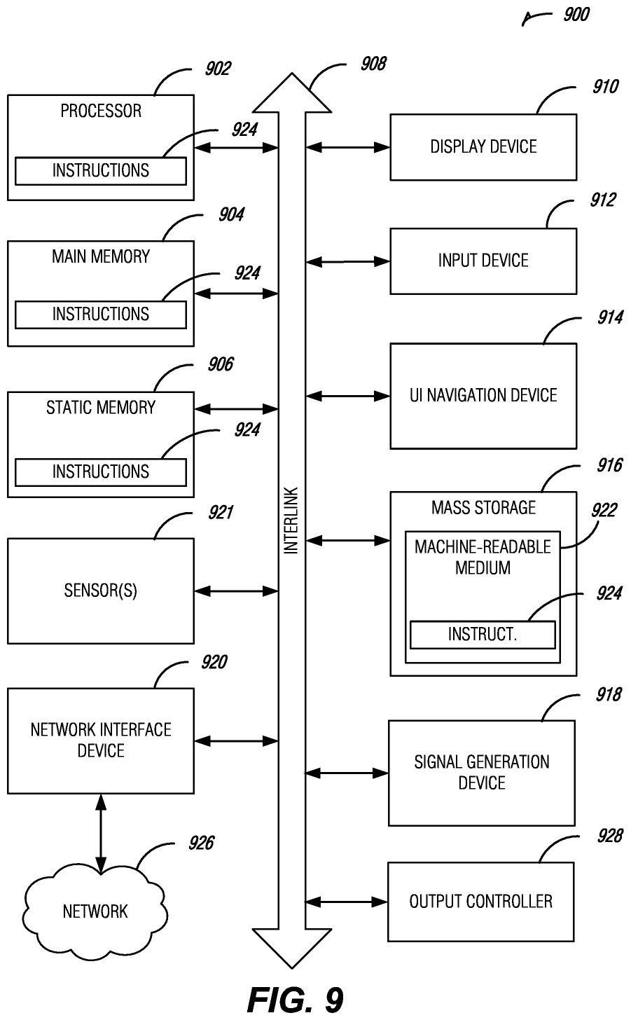

FIG. 9 illustrates a block diagram of an example machine 900 upon which any one or more of the techniques (e.g., methodologies) discussed herein can perform. In alternative embodiments, the machine 900 can operate as a standalone device or can be connected (e.g., networked) to other machines. In a networked deployment, the machine 900 can operate in the capacity of a server machine, a client machine, or both in server-client network environments. In an example, the machine 900 can act as a peer machine in peer-to-peer (P2P) (or other distributed) network environment. The machine 900 can be a personal computer (PC), a tablet PC, a set-top box (STB), a personal digital assistant (PDA), a mobile telephone, a web appliance, a network router, switch or bridge, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (SaaS), other computer cluster configurations.

Examples, as described herein, can include, or can operate by, logic or a number of components, or mechanisms. Circuit sets are a collection of circuits implemented in tangible entities that include hardware (e.g., simple circuits, gates, logic, etc.). Circuit set membership can be flexible over time and underlying hardware variability. Circuit sets include members that can, alone or in combination, perform specified operations when operating. In an example, hardware of the circuit set can be immutably designed to carry out a specific operation (e.g., hardwired). In an example, the hardware of the circuit set can include variably connected physical components (e.g., execution units, transistors, simple circuits, etc.) including a computer readable medium physically modified (e.g., magnetically, electrically, moveable placement of invariant massed particles, etc.) to encode instructions of the specific operation. In connecting the physical components, the underlying electrical properties of a hardware constituent are changed, for example, from an insulator to a conductor or vice versa. The instructions enable embedded hardware (e.g., the execution units or a loading mechanism) to create members of the circuit set in hardware via the variable connections to carry out portions of the specific operation when in operation. Accordingly, the computer readable medium is communicatively coupled to the other components of the circuit set member when the device is operating. In an example, any of the physical components can be used in more than one member of more than one circuit set. For example, under operation, execution units can be used in a first circuit of a first circuit set at one point in time and reused by a second circuit in the first circuit set, or by a third circuit in a second circuit set at a different time.

Machine (e.g., computer system) 900 can include a hardware processor 902 (e.g., a central processing unit (CPU), a graphics processing unit (GPU), a hardware processor core, or any combination thereof), a main memory 904 and a static memory 906, some or all of which can communicate with each other via an interlink (e.g., bus) 908. The machine 900 can further include a display unit 910, an alphanumeric input device 912 (e.g., a keyboard), and a user interface (UI) navigation device 914 (e.g., a mouse). In an example, the display unit 910, input device 912 and UI navigation device 914 can be a touch screen display. The machine 900 can additionally include a storage device (e.g., drive unit) 916, a signal generation device 918 (e.g., a speaker), a network interface device 920, and one or more sensors 921, such as a global positioning system (GPS) sensor, compass, accelerometer, or other sensors. The machine 900 can include an output controller 928, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

The storage device 916 can include a machine readable medium 922 on which is stored one or more sets of data structures or instructions 924 (e.g., software) embodying or utilized by any one or more of the techniques or functions described herein. The instructions 924 can also reside, completely or at least partially, within the main memory 904, within static memory 906, or within the hardware processor 902 during execution thereof by the machine 900. In an example, one or any combination of the hardware processor 902, the main memory 904, the static memory 906, or the storage device 916 can constitute machine readable media.

While the machine readable medium 922 is illustrated as a single medium, the term “machine readable medium” can include a single medium or multiple media (e.g., a centralized or distributed database, and/or associated caches and servers) configured to store the one or more instructions 924.

The term “machine readable medium” can include any medium that is capable of storing, encoding, or carrying instructions for execution by the machine 900 and that cause the machine 900 to perform any one or more of the techniques of the present disclosure, or that is capable of storing, encoding or carrying data structures used by or associated with such instructions. Non-limiting machine readable medium examples can include solid-state memories, and optical and magnetic media. In an example, machine readable media can exclude transitory propagating signals (e.g., non-transitory machine-readable storage media). Specific examples of non-transitory machine-readable storage media can include: non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; and CD-ROM and DVD-ROM disks.

The instructions 924 can further be transmitted or received over a communications network 926 using a transmission medium via the network interface device 920 utilizing any one of a number of transfer protocols (e.g., frame relay, internet protocol (IP), transmission control protocol (TCP), user datagram protocol (UDP), hypertext transfer protocol (HTTP), etc.). Example communication networks can include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.11 family of standards known as Wi-Fi®, LoRa®/LoRaWAN® LPWAN standards, etc.), IEEE 802.15.4 family of standards, peer-to-peer (P2P) networks, 3rd Generation Partnership Project (3GPP) standards for 4G and 5G wireless communication including: 3GPP Long-Term evolution (LTE) family of standards, 3GPP LTE Advanced family of standards, 3GPP LTE Advanced Pro family of standards, 3GPP New Radio (NR) family of standards, among others. In an example, the network interface device 920 can include one or more physical jacks (e.g., Ethernet, coaxial, or phone jacks) or one or more antennas to connect to the communications network 926. In an example, the network interface device 920 can include a plurality of antennas to wirelessly communicate using at least one of single-input multiple-output (SIMO), multiple-input multiple-output (MIMO), or multiple-input single-output (MISO) techniques. The term “transmission medium” shall be taken to include any intangible medium that is capable of storing, encoding or carrying instructions for execution by the machine 900, and includes digital or analog communications signals or other intangible medium to facilitate communication of such software.

### Additional Notes & Examples

Example 1 is a method for characterization of laser transmitter thermal properties comprising: collecting a set of bias current-temperature pairs for a laser diode; calculating a bias current-temperature curve for the laser diode using the set of bias current-temperature pairs; assigning a timestamp to the bias current-temperature curve; storing the bias current-temperature curve and the timestamp in a non-volatile memory device communicatively coupled to a laser device that includes, the laser diode; and transmitting the bias current-temperature curve and the timestamp to a cloud-based storage facility.

In Example 2, the subject matter of Example 1 includes, adjusting an environmental temperature of the laser diode from a lowest operating temperature to a highest operating temperature during manufacturing testing of the laser diode, wherein the set of bias current-temperature pairs comprise bias current-temperature pairs collected at a variety of temperatures from the lowest operating temperature to the highest operating temperature.

In Example 3, the subject matter of Examples 1-2 wherein, the set of bias current-temperature pairs are collected at a variety of environmental temperatures experienced by the laser diode during operation.

In Example 4, the subject matter of Examples 1-3 includes, calculating a temperature error rate for a temperature sensor collecting a temperature of the laser diode; and adjusting the bias current-temperature curve using the temperature error rate.

In Example 5, the subject matter of Examples 1-4 includes, calculating a current error rate for a current sensor collecting a current of the laser diode; and adjusting the bias current-temperature curve using the current error rate.

In Example 6, the subject matter of Examples 1-5 includes, collecting a current bias current-temperature pair for the laser diode; transmitting the current bias current-temperature pair to the cloud-based storage facility; receiving an age value for the laser diode based on the current bias current-temperature pair; and storing the age value in the non-volatile memory device communicatively coupled to a laser device.

In Example 7, the subject matter of Examples 1-6 wherein, the laser diode transmits and receives optical data signals in a passive optical network.

Example 8 is a system for characterization of laser transmitter thermal properties comprising: at least one processor; and memory comprising instructions that, when executed by the at least one processor, cause the at least one processor to perform operations to: collect a set of bias current-temperature pairs for a laser diode; calculate a bias current-temperature curve for the laser diode using the set of bias current-temperature pairs; assign a timestamp to the bias current-temperature curve; store the bias current-temperature curve and the timestamp in a non-volatile memory device communicatively coupled to a laser device that includes, the laser diode; and transmit the bias current-temperature curve and the timestamp to a cloud-based storage facility.

In Example 9, the subject matter of Example 8 includes, the memory further comprising instructions that, when executed by the at least one processor, cause the at least one processor to perform operations to: adjust an environmental temperature of the laser diode from a lowest operating temperature to a highest operating temperature during manufacturing testing of the laser diode, wherein the set of bias current-temperature pairs comprise bias current-temperature pairs collected at a variety of temperatures from the lowest operating temperature to the highest operating temperature.

In Example 10, the subject matter of Examples 8-9 wherein, the set of bias current-temperature pairs are collected at a variety of environmental temperatures experienced by the laser diode during operation.

In Example 11, the subject matter of Examples 8-10 includes, the memory further comprising instructions that, when executed by the at least one processor, cause the at least one processor to perform operations to: calculate a temperature error rate for a temperature sensor collecting a temperature of the laser diode; and adjust the bias current-temperature curve using the temperature error rate.

In Example 12, the subject matter of Examples 8-11 includes, the memory further comprising instructions that, when executed by the at least one processor, cause the at least one processor to perform operations to: calculate a current error rate for a current sensor collecting a current of the laser diode; and adjust the bias current-temperature curve using the current error rate.

In Example 13, the subject matter of Examples 8-12 includes, the memory further comprising instructions that, when executed by the at least one processor, cause the at least one processor to perform operations to: collect a current bias current-temperature pair for the laser diode; transmit the current bias current-temperature pair to the cloud-based storage facility; receive an age value for the laser diode based on the current bias current-temperature pair; and store the age value in the non-volatile memory device communicatively coupled to a laser device.

In Example 14, the subject matter of Examples 8-13 wherein, the laser diode transmits and receives optical data signals in a passive optical network.

Example 15 is at least one non-transitory machine-readable medium including instructions for characterization of laser transmitter thermal properties that, when executed by at least one processor, cause the at least one processor to perform operations to: collect a set of bias current-temperature pairs for a laser diode; calculate a bias current-temperature curve for the laser diode using the set of bias current-temperature pairs; assign a timestamp to the bias current-temperature curve; store the bias current-temperature curve and the timestamp in a non-volatile memory device communicatively coupled to a laser device that includes, the laser diode; and transmit the bias current-temperature curve and the timestamp to a cloud-based storage facility.

In Example 16, the subject matter of Example 15 includes, instructions that, when executed by the at least one processor, cause the at least one processor to perform operations to: adjust an environmental temperature of the laser diode from a lowest operating temperature to a highest operating temperature during manufacturing testing of the laser diode, wherein the set of bias current-temperature pairs comprise bias current-temperature pairs collected at a variety of temperatures from the lowest operating temperature to the highest operating temperature.

In Example 17, the subject matter of Examples 15-16 wherein, the set of bias current-temperature pairs are collected at a variety of environmental temperatures experienced by the laser diode during operation.

In Example 18, the subject matter of Examples 15-17 includes, instructions that, when executed by the at least one processor, cause the at least one processor to perform operations to: calculate a temperature error rate for a temperature sensor collecting a temperature of the laser diode; and adjust the bias current-temperature curve using the temperature error rate.

In Example 19, the subject matter of Examples 15-18 includes, instructions that, when executed by the at least one processor, cause the at least one processor to perform operations to: calculate a current error rate for a current sensor collecting a current of the laser diode; and adjust the bias current-temperature curve using the current error rate.

In Example 20, the subject matter of Examples 15-19 includes, instructions that, when executed by the at least one processor, cause the at least one processor to perform operations to: collect a current bias current-temperature pair for the laser diode; transmit the current bias current-temperature pair to the cloud-based storage facility; receive an age value for the laser diode based on the current bias current-temperature pair; and store the age value in the non-volatile memory device communicatively coupled to a laser device.

In Example 21, the subject matter of Examples 15-20 wherein, the laser diode transmits and receives optical data signals in a passive optical network.

Example 22 is a method for characterization of laser transmitter thermal properties comprising: receiving a set of bias current-temperature curves for a laser diode, the set of bias current-temperature curves having timestamps between a first time and a subsequent second time; evaluating the set of bias current-temperature curves to calculate a bias current-temperature profile for the laser diode; receiving a current bias current-temperature pair for the laser diode; and calculating an age of the laser diode by evaluating the current bias current-temperature pair with the bias current-temperature profile of the laser diode, wherein the age of the laser diode indicates an operational life stage of the laser diode.

In Example 23, the subject matter of Example 22 wherein, calculating the age of the laser diode by evaluating the current bias current-temperature pair with the bias current-temperature profile of the laser diode further comprises: calculating a number of operating minutes of the laser diode at a temperature of the current bias current-temperature pair; determining an acceleration factor for the temperature using the bias current-temperature profile; and calculating the age of the laser diode by applying the acceleration factor to an aging algorithm and processing the number of operating minutes using the aging algorithm.

In Example 24, the subject matter of Examples 22-23 wherein, calculating the age of the laser diode by evaluating the current bias current-temperature pair with the bias current-temperature profile of the laser diode further comprises: calculating an individualized laser bias current increase threshold by comparing the bias current-temperature profile of the laser diode to a current bias current-temperature curve, wherein the bias current-temperature profile of the laser diode is established at initial installation of the laser diode; and determining the age of the laser diode by comparing the current bias current-temperature pair to the individualized laser bias current increase threshold.

In Example 25, the subject matter of Examples 22-24 wherein, calculating the age of the laser diode by evaluating the current bias current-temperature pair with the bias current-temperature profile of the laser diode further comprises: setting a threshold of change of current over time for a range of temperatures using the bias current-temperature profile; identifying that the current bias current-temperature pair is an inflection point based on a comparison of the current bias current-temperature pair to the threshold of change of current over time; and determining the age of the laser diode based on the inflection point.

In Example 26, the subject matter of Examples 22-25 includes, determining that the age of the laser diode is outside a laser diode age threshold; generating a laser aging notification for the laser diode; and transmitting the laser aging notification to a user computing device.

In Example 27, the subject matter of Examples 22-26 wherein, the laser diode transmits and receives optical data signals in a passive optical network.

In Example 28, the subject matter of Examples 22-27 wherein, the laser diode is included in an optical networking unit.

Example 29 is a system for characterization of laser transmitter thermal properties comprising: at least one processor; and memory comprising instructions that, when executed by the at least one processor, cause the at least one processor to perform operations to: receive a set of bias current-temperature curves for a laser diode, the set of bias current-temperature curves having timestamps between a first time and a subsequent second time; evaluate the set of bias current-temperature curves to calculate a bias current-temperature profile for the laser diode; receive a current bias current-temperature pair for the laser diode; and calculate an age of the laser diode by evaluating the current bias current-temperature pair with the bias current-temperature profile of the laser diode, wherein the age of the laser diode indicates an operational life stage of the laser diode.

In Example 30, the subject matter of Example 29 wherein, the instructions to calculate the age of the laser diode by evaluating the current bias current-temperature pair with the bias current-temperature profile of the laser diode further comprises instructions that, when executed by the at least one processor, cause the at least one processor to perform operations to: calculate a number of operating minutes of the laser diode at a temperature of the current bias current-temperature pair; determine an acceleration factor for the temperature using the bias current-temperature profile; and calculate the age of the laser diode by applying the acceleration factor to an aging algorithm and processing the number of operating minutes using the aging algorithm.

In Example 31, the subject matter of Examples 29-30 wherein, the instructions to calculate the age of the laser diode by evaluating the current bias current-temperature pair with the bias current-temperature profile of the laser diode further comprises instructions that, when executed by the at least one processor, cause the at least one processor to perform operations to: calculate an individualized laser bias current increase threshold by comparing the bias current-temperature profile of the laser diode to a current bias current-temperature curve, wherein the bias current-temperature profile of the laser diode is established at initial installation of the laser diode; and determine the age of the laser diode by comparing the current bias current-temperature pair to the individualized laser bias current increase threshold.

In Example 32, the subject matter of Examples 29-31 wherein, the instructions to calculate the age of the laser diode by evaluating the current bias current-temperature pair with the bias current-temperature profile of the laser diode further comprises instructions that, when executed by the at least one processor, cause the at least one processor to perform operations to: set a threshold of change of current over time for a range of temperatures using the bias current-temperature profile; identify that the current bias current-temperature pair is an inflection point based on a comparison of the current bias current-temperature pair to the threshold of change of current over time; and determine the age of the laser diode based on the inflection point.

In Example 33, the subject matter of Examples 29-32 includes, the memory further comprising instructions that, when executed by the at least one processor, cause the at least one processor to perform operations to: determine that the age of the laser diode is outside a laser diode age threshold; generate a laser aging notification for the laser diode; and transmit the laser aging notification to a user computing device.

In Example 34, the subject matter of Examples 29-33 wherein, the laser diode transmits and receives optical data signals in a passive optical network.

In Example 35, the subject matter of Examples 29-34 wherein, the laser diode is included in an optical networking unit.

Example 36 is at least one non-transitory machine-readable medium including instructions for characterization of laser transmitter thermal properties that, when executed by at least one processor, cause the at least one processor to perform operations to: receive a set of bias current-temperature curves for a laser diode, the set of bias current-temperature curves having timestamps between a first time and a subsequent second time; evaluate the set of bias current-temperature curves to calculate a bias current-temperature profile for the laser diode; receive a current bias current-temperature pair for the laser diode; and calculate an age of the laser diode by evaluating the current bias current-temperature pair with the bias current-temperature profile of the laser diode, wherein the age of the laser diode indicates an operational life stage of the laser diode.

In Example 37, the subject matter of Example 36 wherein, the instructions to calculate the age of the laser diode by evaluating the current bias current-temperature pair with the bias current-temperature profile of the laser diode further comprises instructions that, when executed by the at least one processor, cause the at least one processor to perform operations to: calculate a number of operating minutes of the laser diode at a temperature of the current bias current-temperature pair; determine an acceleration factor for the temperature using the bias current-temperature profile; and calculate the age of the laser diode by applying the acceleration factor to an aging algorithm and processing the number of operating minutes using the aging algorithm.

In Example 38, the subject matter of Examples 36-37 wherein, the instructions to calculate the age of the laser diode by evaluating the current bias current-temperature pair with the bias current-temperature profile of the laser diode further comprises instructions that, when executed by the at least one processor, cause the at least one processor to perform operations to: calculate an individualized laser bias current increase threshold by comparing the bias current-temperature profile of the laser diode to a current bias current-temperature curve, wherein the bias current-temperature profile of the laser diode is established at initial installation of the laser diode; and determine the age of the laser diode by comparing the current bias current-temperature pair to the individualized laser bias current increase threshold.

In Example 39, the subject matter of Examples 36-38 wherein, the instructions to calculate the age of the laser diode by evaluating the current bias current-temperature pair with the bias current-temperature profile of the laser diode further comprises instructions that, when executed by the at least one processor, cause the at least one processor to perform operations to: set a threshold of change of current over time for a range of temperatures using the bias current-temperature profile; identify that the current bias current-temperature pair is an inflection point based on a comparison of the current bias current-temperature pair to the threshold of change of current over time; and determine the age of the laser diode based on the inflection point.

In Example 40, the subject matter of Examples 36-39 includes, instructions that, when executed by the at least one processor, cause the at least one processor to perform operations to: determine that the age of the laser diode is outside a laser diode age threshold; generate a laser aging notification for the laser diode; and transmit the laser aging notification to a user computing device.

In Example 41, the subject matter of Examples 36-40 wherein, the laser diode transmits and receives optical data signals in a passive optical network.

In Example 42, the subject matter of Examples 36-41 wherein, the laser diode is included in an optical networking unit.

Example 43 is at least one machine-readable medium including instructions that, when executed by processing circuitry, cause the processing circuitry to perform operations to implement of any of Examples 1-42.

Example 44 is an apparatus comprising means to implement of any of Examples 1-42.

Example 45 is a system to implement of any of Examples 1-42.

Example 46 is a method to implement of any of Examples 1-42.

The above detailed description includes references to the accompanying drawings, which form a part of the detailed description. The drawings show, by way of illustration, specific embodiments that can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

All publications, patents, and patent documents referred to in this document are incorporated by reference herein in their entirety, as though individually incorporated by reference. In the event of inconsistent usages between this document and those documents so incorporated by reference, the usage in the incorporated reference(s) should be considered supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The above description is intended to be illustrative, and not restrictive. For example, the above-described examples (or one or more aspects thereof) can be used in combination with each other. Other embodiments can be used, such as by one of ordinary skill in the art upon reviewing the above description. The Abstract is to allow the reader to quickly ascertain the nature of the technical disclosure and is submitted with the understanding that it will not be used to interpret or limit the scope or meaning of the claims. Also, in the above Detailed Description, various features can be grouped together to streamline the disclosure. This should not be interpreted as intending that an unclaimed disclosed feature is essential to any claim. Rather, inventive subject matter can lie in less than all features of a particular disclosed embodiment. Thus, the following claims are hereby incorporated into the Detailed Description, with each claim standing on its own as a separate embodiment. The scope of the embodiments should be determined with reference to the appended claims, along with the full scope of equivalents to which such claims are entitled.

What is claimed is:

1. A system for characterization of laser transmitter thermal properties comprising:
at least one processor; and
memory comprising instructions that, when executed by the at least one processor, cause the at least one processor to perform operations to:
collect a set of bias current-temperature pairs for a laser diode;
calculate a bias current-temperature curve for the laser diode using the set of bias current-temperature pairs;
assign a timestamp to the bias current-temperature curve;
store the bias current-temperature curve and the timestamp in a non-volatile memory device communicatively coupled to a laser device that includes the laser diode; and
transmit the bias current-temperature curve and the timestamp to a cloud-based storage facility.

2. The system of 1, the memory further comprising instructions that, when executed by the at least one processor, cause the at least one processor to perform operations to:
adjust an environmental temperature of the laser diode from a lowest operating temperature to a highest operating temperature during manufacturing testing of the laser diode, wherein the set of bias current-temperature pairs comprise bias current-temperature pairs collected at a variety of temperatures from the lowest operating temperature to the highest operating temperature.

3. The system of 1, wherein the set of bias current-temperature pairs are collected at a variety of environmental temperatures experienced by the laser diode during operation.

4. The system of 1, the memory further comprising instructions that, when executed by the at least one processor, cause the at least one processor to perform operations to:
calculate a temperature error rate for a temperature sensor collecting a temperature of the laser diode; and
adjust the bias current-temperature curve using the temperature error rate.

5. The system of 1, the memory further comprising instructions that, when executed by the at least one processor, cause the at least one processor to perform operations to:
calculate a current error rate for a current sensor collecting a current of the laser diode; and
adjust the bias current-temperature curve using the current error rate.

6. The system of 1, the memory further comprising instructions that, when executed by the at least one processor, cause the at least one processor to perform operations to:
collect a current bias current-temperature pair for the laser diode;
transmit the current bias current-temperature pair to the cloud-based storage facility;
receive an age value for the laser diode based on the current bias current-temperature pair; and
store the age value in the non-volatile memory device communicatively coupled to a laser device.

7. The system of 1, wherein the laser diode transmits and receives optical data signals in a passive optical network.

8. At least one non-transitory machine-readable medium including instructions for characterization of laser transmitter thermal properties that, when executed by at least one processor, cause the at least one processor to perform operations to:
collect a set of bias current-temperature pairs for a laser diode;
calculate a bias current-temperature curve for the laser diode using the set of bias current-temperature pairs;
assign a timestamp to the bias current-temperature curve;
store the bias current-temperature curve and the timestamp in a non-volatile memory device communicatively coupled to a laser device that includes the laser diode; and
transmit the bias current-temperature curve and the timestamp to a cloud-based storage facility.

9. The at least one non-transitory machine-readable medium of 8, further comprising instructions that, when executed by the at least one processor, cause the at least one processor to perform operations to:
adjust an environmental temperature of the laser diode from a lowest operating temperature to a highest operating temperature during manufacturing testing of the laser diode, wherein the set of bias current-temperature pairs comprise bias current-temperature pairs collected at a variety of temperatures from the lowest operating temperature to the highest operating temperature.

10. The at least one non-transitory machine-readable medium of 8, wherein the set of bias current-temperature pairs are collected at a variety of environmental temperatures experienced by the laser diode during operation.

11. The at least one non-transitory machine-readable medium of 8, further comprising instructions that, when executed by the at least one processor, cause the at least one processor to perform operations to:
calculate a temperature error rate for a temperature sensor collecting a temperature of the laser diode; and
adjust the bias current-temperature curve using the temperature error rate.

12. The at least one non-transitory machine-readable medium of 8, further comprising instructions that, when executed by the at least one processor, cause the at least one processor to perform operations to:
calculate a current error rate for a current sensor collecting a current of the laser diode; and
adjust the bias current-temperature curve using the current error rate.

13. The at least one non-transitory machine-readable medium of 8, further comprising instructions that, when executed by the at least one processor, cause the at least one processor to perform operations to:
collect a current bias current-temperature pair for the laser diode;
transmit the current bias current-temperature pair to the cloud-based storage facility;
receive an age value for the laser diode based on the current bias current-temperature pair; and
store the age value in the non-volatile memory device communicatively coupled to a laser device.

14. The at least one non-transitory machine-readable medium of 8, wherein the laser diode transmits and receives optical data signals in a passive optical network.

15. A method for characterization of laser transmitter thermal properties comprising:
receiving a set of bias current-temperature curves for a laser diode, the set of bias current-temperature curves having timestamps between a first time and a subsequent second time;
evaluating the set of bias current-temperature curves to calculate a bias current-temperature profile for the laser diode;
receiving a current bias current-temperature pair for the laser diode; and
calculating an age of the laser diode by evaluating the current bias current-temperature pair with the bias current-temperature profile of the laser diode, wherein the age of the laser diode indicates an operational life stage of the laser diode.

16. The method of 15, wherein calculating the age of the laser diode by evaluating the current bias current-temperature pair with the bias current-temperature profile of the laser diode further comprises:
calculating a number of operating minutes of the laser diode at a temperature of the current bias current-temperature pair;
determining an acceleration factor for the temperature using the bias current-temperature profile; and
calculating the age of the laser diode by applying the acceleration factor to an aging algorithm and processing the number of operating minutes using the aging algorithm.

17. The method of 15, wherein calculating the age of the laser diode by evaluating the current bias current-temperature pair with the bias current-temperature profile of the laser diode further comprises:
calculating an individualized laser bias current increase threshold by comparing the bias current-temperature profile of the laser diode to a current bias current-temperature curve, wherein the bias current-temperature profile of the laser diode is established at initial installation of the laser diode; and
determining the age of the laser diode by comparing the current bias current-temperature pair to the individualized laser bias current increase threshold.

18. The method of 15, wherein calculating the age of the laser diode by evaluating the current bias current-temperature pair with the bias current-temperature profile of the laser diode further comprises:
setting a threshold of change of current over time for a range of temperatures using the bias current-temperature profile;
identifying that the current bias current-temperature pair is an inflection point based on a comparison of the current bias current-temperature pair to the threshold of change of current over time; and
determining the age of the laser diode based on the inflection point.

19. The method of 15, further comprising:
determining that the age of the laser diode is outside a laser diode age threshold;
generating a laser aging notification for the laser diode; and
transmitting the laser aging notification to a user computing device.

20. The method of 15, wherein the laser diode transmits and receives optical data signals in a passive optical network.
